(19) United States
(12) Patent Application Publication
(10) Pub. No.: US 2014/0167152 A1
(43) Pub. Date: Jun. 19, 2014

(54) Reduced Gate Charge Trench Field-Effect Transistor

(71) Applicant: International Rectifier Corporation, El Segundo, CA (US)

(72) Inventor: Ling Ma, Redondo Beach, CA (US)

(73) Assignee: International Rectifier Corporation, El Segundo, CA (US)

(21) Appl. No.: 14/095,063

(22) Filed: Dec. 3, 2013

Related U.S. Application Data
(60) Provisional application No. 61/737,038, filed on Dec. 13, 2012.

(51) Int. Cl. H01L 29/78; H01L 29/66

(52) U.S. Cl. CPC H01L 29/7813; H01L 29/66734
USPC 257/330; 438/270

(57) ABSTRACT

In one implementation, a trench field-effect transistor (trench FET) can include a semiconductor substrate including a drain region, a drift zone over the drain region, and first and second gate trenches including a gate dielectric and respective gate electrodes disposed therein, also over the drain region. The trench FET can further include a depletion trench situated between the first and second gate trenches, the depletion trench including a trench insulator. The trench insulator adjoins the gate electrodes and the gate dielectric so as to reduce a gate charge of the trench FET.

The present application claims the benefit of and priority to a provisional application entitled “Reduced Gate Charge Trench MOSFET,” Ser. No. 61/737,038 filed on Dec. 13, 2012. The disclosure in this provisional application is hereby incorporated fully by reference into the present application.

### BACKGROUND

### Background Art

Group IV power transistors, such as silicon based trench type field-effect transistors (trench FETs) are used in a variety of applications. For example, silicon based trench metal-oxide-semiconductor FETs (trench MOSFETs) may be used to implement a power converter, such as a synchronous rectifier, or a direct current (DC) to DC power converter.

For many trench FET applications, it is desirable to reduce the on-resistance (R_{dson}) of the transistor. In addition, in applications for which high switching speeds are necessary or desirable, it may also be advantageous to reduce gate charge (Q_{g}), so as to reduce switching loss. However, conventional strategies for reducing on-resistance, such as increasing channel density for example, typically not only increase gate charge, but may undesirably increase the product of on-resistance and gate charge (i.e., R_{dson}*Q_{g}) as well.

### SUMMARY

The present disclosure is directed to a reduced gate charge trench field-effect transistor, substantially as shown in and/or described in connection with at least one of the figures, and as set forth more completely in the claims.

### BRIEF DESCRIPTION OF THE DRAWINGS

FIG. 1 shows a flowchart presenting one exemplary method for fabricating a reduced gate charge trench field-effect transistor (trench FET).

FIG. 2A shows an exemplary structure corresponding to an initial stage of the method described in FIG. 1.

FIG. 2B shows the exemplary structure in FIG. 2A at an intermediate stage of the method described in FIG. 1.

FIG. 2C shows the exemplary structure in FIG. 2B at another intermediate stage of the method described in FIG. 1.

FIG. 2D shows the exemplary structure in FIG. 2C at another intermediate stage of the method described in FIG. 1.

FIG. 2E shows the exemplary structure in FIG. 2D at another intermediate stage of the method described in FIG. 1.

FIG. 2F shows a cross-sectional view of a reduced gate charge trench FET, according to one implementation.

FIG. 3 shows a cross-sectional view of a reduced gate charge trench FET, according to another implementation.

### DETAILED DESCRIPTION

The following description contains specific information pertaining to implementations in the present disclosure. One skilled in the art will recognize that the present disclosure may be implemented in a manner different from that specifically discussed herein. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

As stated above, group IV power transistors, such as silicon based trench type field-effect transistors (trench FETs) are used in a variety of applications. For example, silicon based trench metal-oxide-semiconductor FETs (trench MOSFETs) may be used to implement a power converter, such as a synchronous rectifier, or a direct current (DC) to DC power converter. For many trench FET applications, it is desirable to reduce the on-resistance (R_{dson}) of the transistor. Moreover, in applications for which high switching speeds are necessary or desirable, it may also be advantageous to reduce gate charge (Q_{g}), so as to reduce switching loss. However, conventional strategies for reducing on-resistance, such as increasing channel density for example, typically not only increase gate charge, but may undesirably increase the product of on-resistance and gate charge (i.e., R_{dson}*Q_{g}) as well.

The present application discloses a group IV trench FET and a method for its fabrication that reduces Q_{g}, and in some implementations concurrently reduces the product R_{dson}*Q_{g}. For example, by configuring a gate electrode and a gate dielectric so as to be adjoined by a thicker trench insulator used to line a depletion trench of the trench FET, the capacitance between the gate electrode and the silicon or other group IV layer in which a gate trench including the gate electrode is disposed, can be reduced. As a result, Q_{g} for the trench FET is reduced, enhancing performance for virtually all high frequency switching applications. In addition, for some applications, for example those requiring a FET operating voltage of approximately eighty volts (80 V) to approximately 100 V, or higher, the implementations disclosed in the present application can advantageously result in a reduction in the product R_{dson}*Q_{g}.

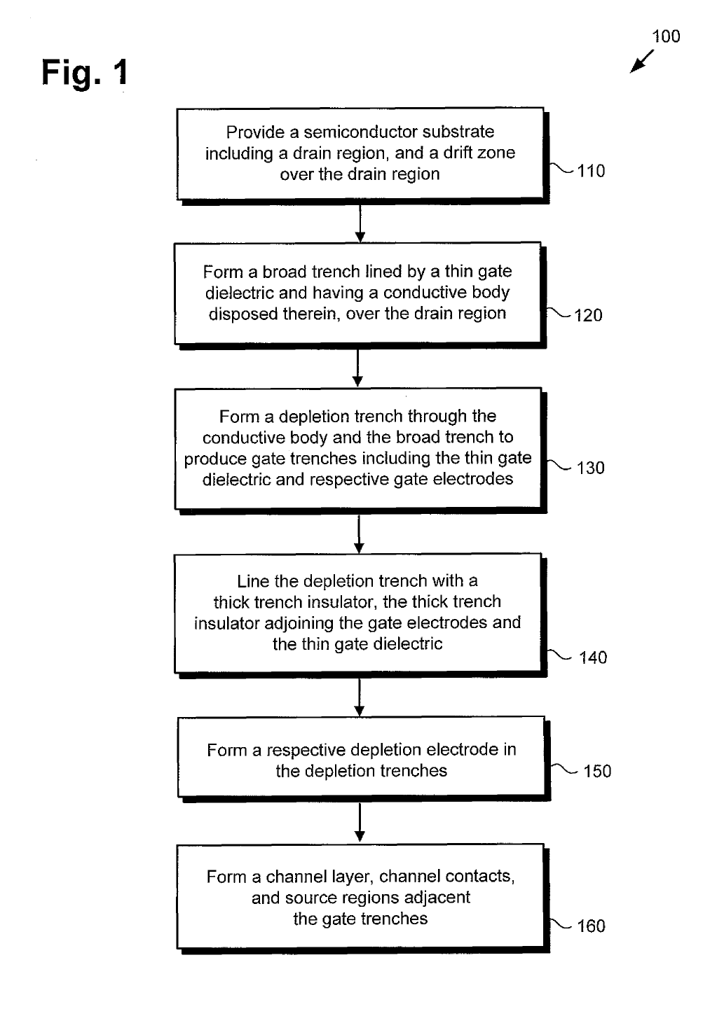

Referring to FIG. 1, FIG. 1 shows flowchart 100 presenting an exemplary method for fabricating a reduced gate charge trench FET, according to one implementation. It is noted that the method described by flowchart 100 is performed on a portion of a processed semiconductor wafer or die, which may include, among other features, a silicon substrate and an epitaxially grown silicon layer, for example.

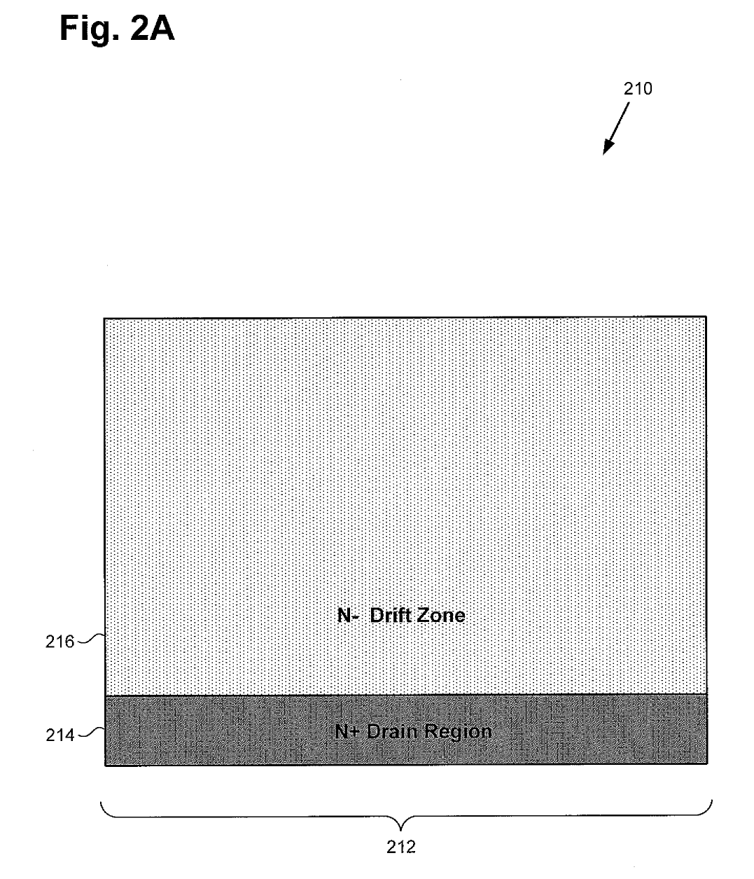

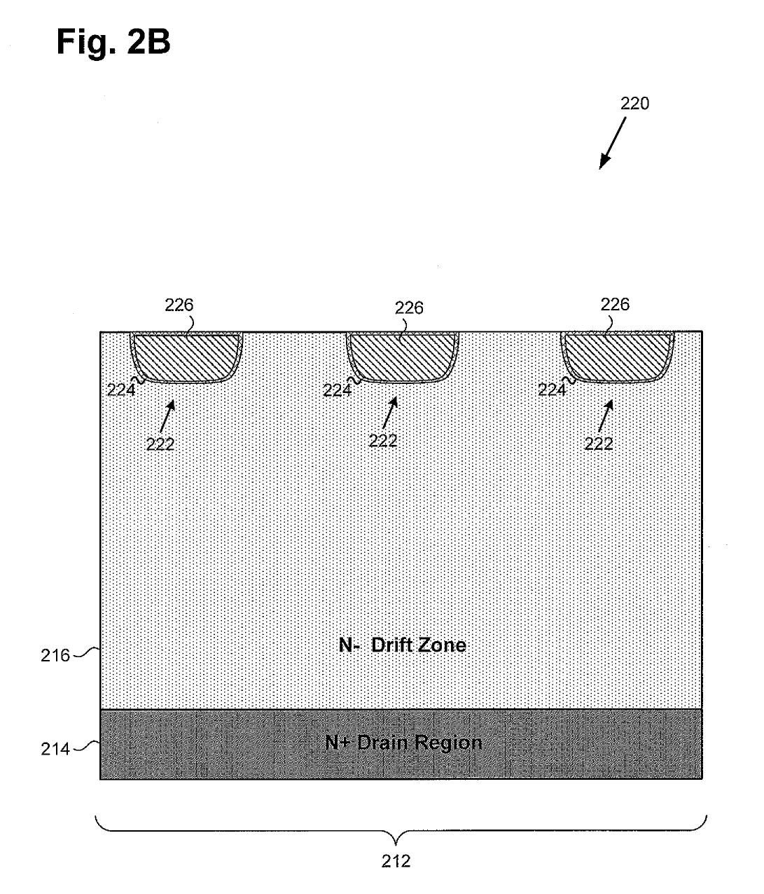

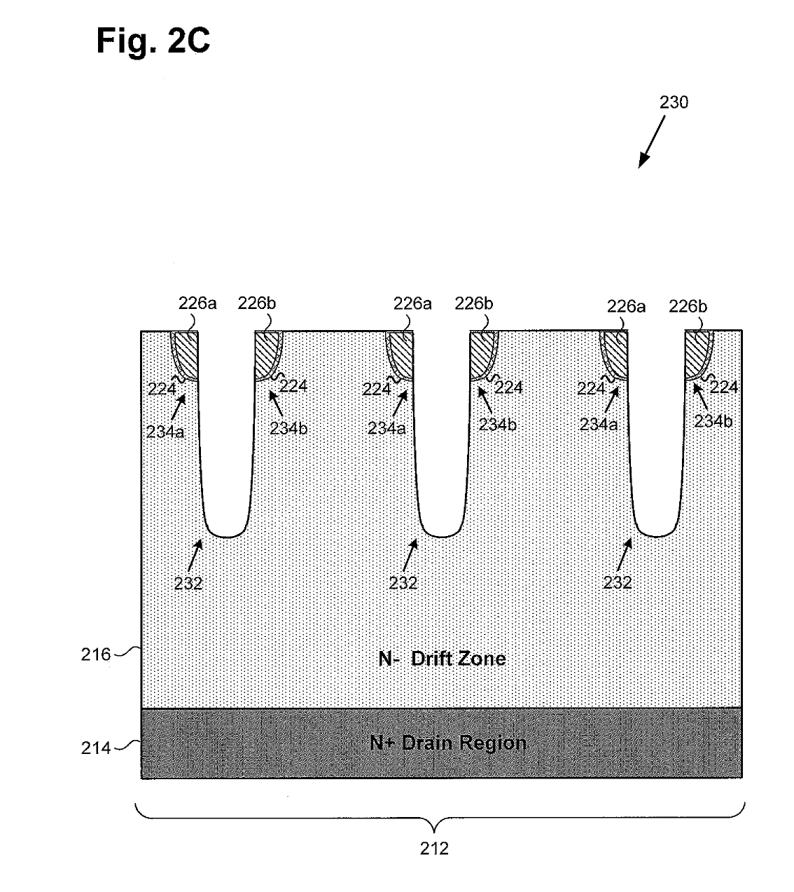

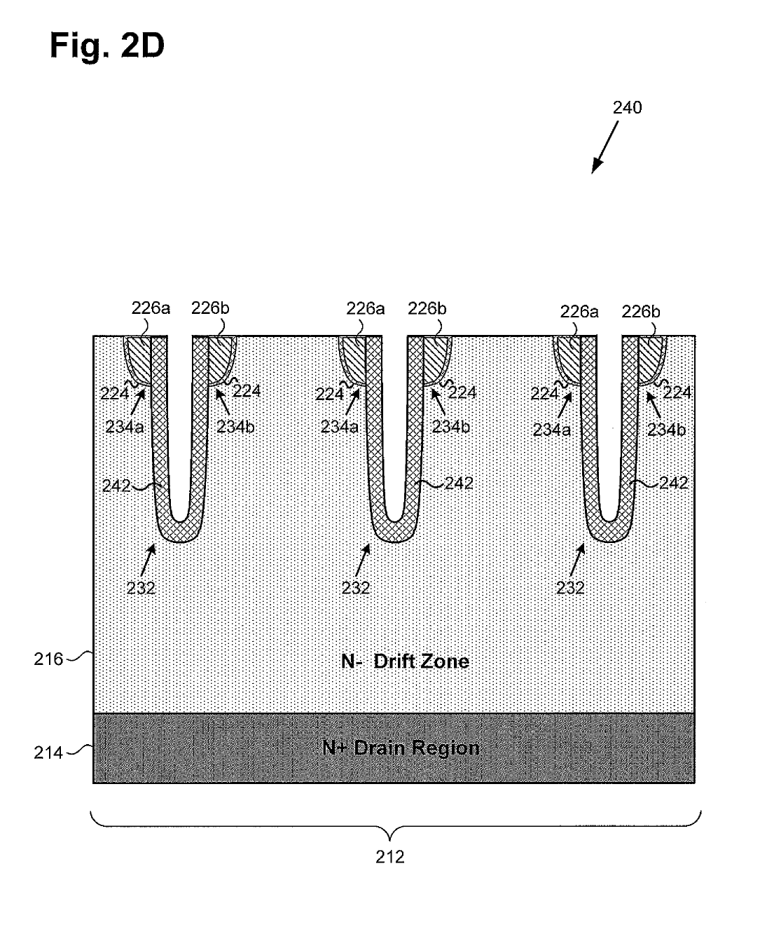

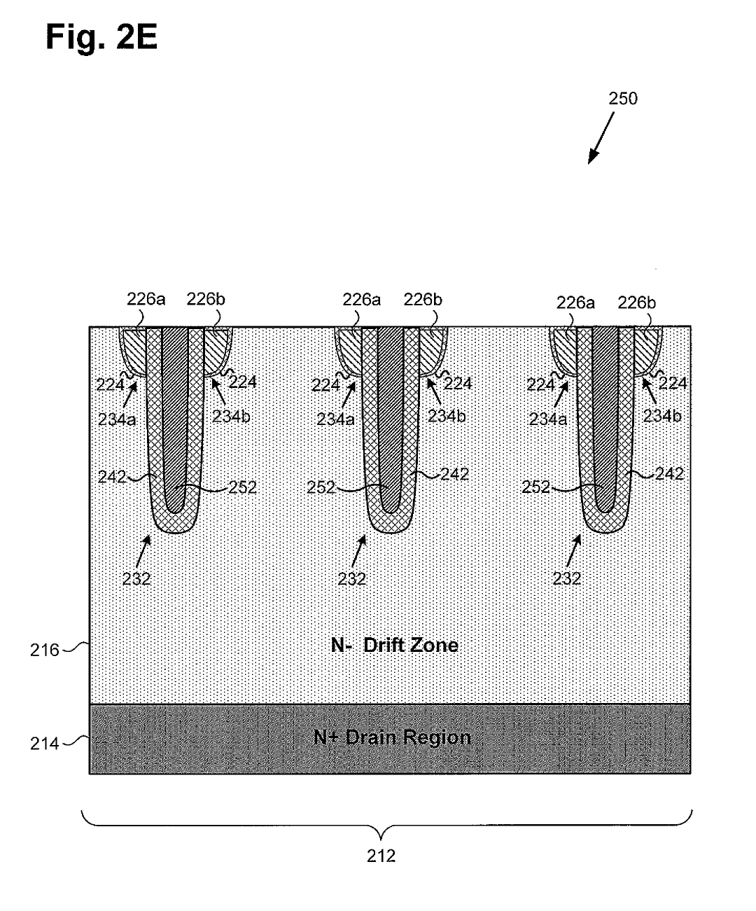

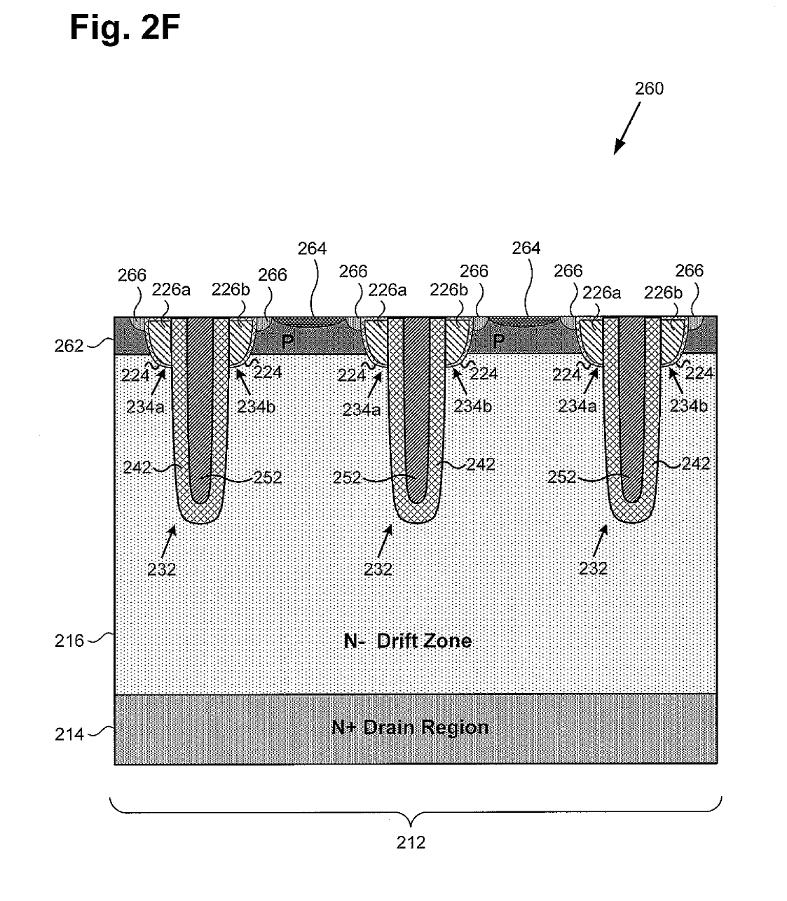

With respect to FIGS. 2A through 2F, structures 210 through 260 shown respectively in those figures illustrate the result of performing the method of flowchart 100 on a semiconductor structure, such as a portion of a semiconductor substrate. For example, structure 210 shows a portion of the semiconductor substrate including a drain region and a drift zone over the drain region (110), structure 220 shows structure 210 after formation of broad trenches lined by a thin gate dielectric and having respective conductive bodies disposed therein (120), structure 230 shows structure 220 after formation of depletion trenches through the conductive bodies and broad trenches (130), and so forth. It is noted that although FIGS. 2A through 2F depict fabrication of an n-channel field-effect transistor (NFET) in silicon, that representation is merely exemplary. In other implementations, other group IV semiconductors can be utilized, such as strained or unstrained germanium, for example. Moreover, in some implementations, the present concepts can be adapted to fabricate a p-channel FET (PFET).

Referring to structure 210, in FIG. 2A, in combination with flowchart 100, in FIG. 1, flowchart 100 begins with providing semiconductor substrate 212 including drain region 214, and drift zone 216 over drain region 214 (110). According to the exemplary implementation of FIG. 2A, drain region 214 is shown as an N+ drain region, and drift zone 216 is shown as an N− drift zone situated over drain region 214. Semiconductor substrate 212 may be a silicon substrate, for example, and may include drift zone 216 formed as an epitaxial silicon layer disposed over drain region 214. Formation of an epitaxial silicon layer may be performed by any suitable method, as known in the art, such as chemical vapor deposition (CVD) or molecular beam epitaxy (MBE), for example.

More generally, however, drift zone 216 may be formed as any suitable group IV layer included in semiconductor structure 210. Thus, in other implementations, drift zone 216 need not be formed of silicon. For example, in one alternative implementation, drift zone 216 can be formed in either a strained or unstained germanium layer formed over drain region 214 of semiconductor substrate 212. Moreover, in some implementations, structure 210 may include additional layers, such as a buffer or field stop layer having the same conductivity type as drain region 214 and drift zone 216, and situated between drain region 214 and drift zone 216 (buffer or field stop layer not shown in FIG. 2A).

Continuing to refer to flowchart 100, in FIG. 1, with additional reference to structure 220, in FIG. 2B, flowchart 100 continues with forming broad trenches 222 lined by thin gate dielectric 224 and having respective conductive bodies 226 formed therein, over drain region 214 (120). Formation of broad trenches 222 can be performed using any techniques known in the art. For example, in one implementation, a photoresist layer may be deposited over drift zone 216 and may be lithographically patterned to provide a mask for formation of broad trenches 222 (photoresist layer not shown). Thereafter, a suitable etch process may be utilized to form broad trenches 222. An example of a suitable etch process for formation of broad trenches 222 is a dry etch process, such as a plasma etch.

Thin gate dielectric 224 may be formed using any material and any technique typically employed in the art. For example, thin gate dielectric 224 may be a gate oxide, such as silicon oxide (SiO₂), or a gate nitride, such as silicon nitride (Si₃N₄), and may be deposited or thermally grown to produce thin gate dielectric 224. In some implementations, for example, thin gate dielectric 224 may be a SiO₂ layer thermally grown to a thickness in a range from approximately 500 angstroms (500 Å) to approximately 1000 Å.

Alternatively, thin gate dielectric 224 may be a high dielectric constant (high-K) dielectric layer suitable for use in a high-K metal gate process. That is to say, for example, thin gate dielectric 224 may be formed of a metal oxide such as hafnium oxide (HfO₂), zirconium oxide (ZrO₂), or the like. Moreover, thin gate dielectric 224 can be fanned by depositing a high-K dielectric material, such as HfO₂ or ZrO₂ so as to line broad trenches 222, utilizing a physical vapor deposition (PVD) process, CVD, or other suitable deposition process.

Conductive bodies 226 may be formed using any material typically utilized in the art. For example, conductive bodies 226 may be formed of conductive polysilicon. However, in implementations in which thin gate dielectric 224 is formed as a high-K dielectric, conductive bodies 226 may be formed of gate metal. Thus, when implemented as part of an NFET, such as an n-channel MOSFET, conductive bodies 226 may be formed of a gate metal suitable for use as an NFET gate. For example, conductive bodies 226 may be formed of tantalum (Ta), tantalum nitride (TaN), titanium nitride (TiN), or other gate metal suitable for utilization in an NFET gate.

Alternatively, when implemented as part of a PFET, such as a p-channel MOSFET, conductive bodies 226 may be formed of a gate metal suitable for use as a PFET gate. For example, in those implementations, conductive bodies 226 may be formed of molybdenum (Mo), ruthenium (Ru), or tantalum carbide nitride (TaCN), for example.

Referring now to structure 230, in FIG. 2C, in combination with FIG. 1, flowchart 100 continues with formation of depletion trenches 232 through conductive bodies 226 and broad trenches 222 to produce gate trenches 234a and 234b including thin gate dielectric 224 and respective gate electrodes 226a and 226b (130). Formation of depletion trenches 232 can be performed using any techniques known in the art. For example, in one implementation, a photoresist layer may be deposited over semiconductor structure 220, in FIG. 2B, and may be lithographically patterned to provide a mask for formation of depletion trenches 232, in FIG. 2C (photoresist layer not shown). Thereafter, a suitable etch process, such as a plasma etch, or other dry etch process, may be utilized to form depletion trenches 232.

As shown in FIG. 2C, depletion trenches 232 extend into drift zone 216, and are situated between respective gate trenches 234a and 234b. As further shown in FIG. 2C, depletion trenches 232 are significantly deeper than gate trenches 234a and 234b. For example, in some implementations, depletion trenches 232 may be from approximately one and a half times deeper to approximately twice as deep as gate trenches 234a and 234b. Moreover, in some implementations, it may be advantageous or desirable for depletion trenches 232 to be more than twice as deep as gate trenches 234a and 234b.

According to the implementation shown in FIG. 2C, depletion trenches are formed through substantially the center of broad trenches 222 of FIG. 2B. As a result, the disposition of gate trenches 234a and 234b including respective gate electrodes 226a and 226b is substantially symmetrical with respect to depletion trenches 232. Moreover, because depletion trenches 232 are formed through conductive bodies 226 and through thin gate dielectric 224, depletion trenches 232 adjoin gate electrodes 226a and 226b, and thin gate dielectric 224.

Moving to structure 240 in FIG. 2D with ongoing reference to FIG. 1, flowchart 100 continues with lining of depletion trenches 232 with thick trench insulator 242, thick trench insulator 242 adjoining gate electrodes 226a and 226b, and thin gate dielectric 224 (140). In some implementations, as shown in FIG. 2D, thick trench insulator 242 may be formed of the same material used to form thin gate dielectric 224. Moreover, in those implementations, thick trench insulator 242 may be formed using the same technique utilized for formation of thin gate dielectric 224.

That is to say, thick trench insulator 242 may be formed as a thermally grown oxide, such as silicon oxide. However, it is noted that even when formed of substantially the same dielectric material and formed using substantially the same fabrication technique, thick trench insulator 242 is distinguishable from thin gate dielectric 224 by being substantially thicker than thin gate dielectric 224. As a specific example, thick trench insulator 242 may be a SiO₂ layer formed to a thickness in a range from approximately 3000 Å to approximately 6000 Å. By way of comparison, and as noted above, thin gate dielectric 224 may be an approximately 500 Å to approximately 1000 Å SiO₂ layer.

Together, thin gate dielectric 224 and thick trench insulator 242 provide gate insulation for gate electrodes 226a and 226b. Disposition of gate electrodes 226a and 226b adjoining depletion trenches 232, and the use of thick trench insulator 242 to form a portion of the gate insulation for gate electrodes 226a and 226b, results in a reduced capacitance between drift zone 216 and gate electrodes 226a and 226b relative to conventional designs. Consequently, the gate charge Q_{g} of a trench FET, such as a trench MOSFET, fabricated based on the method of flowchart 100 can be expected to be reduced, rendering the MOSFET advantageous for use in high frequency switching applications.

As shown by structure 250 in FIG. 2E, flowchart 100 continues with formation of respective depletion electrodes 252 in depletion trenches 232 (150). Depletion electrodes 252 may be formed of the same material and using the same technique utilized for formation of gate electrodes 226a and 226b, i.e., the same material and using the same technique utilized for formation of conductive bodies 226, in FIG. 2B. That is to say, depletion electrodes 252 may be formed of any suitable conductor, such as conductive polysilicon, or metal, for example. Although depletion electrodes 252 can be formed of substantially the same material and may be fabricated using substantially the same technique used to form gate electrodes 226a and 226b, as noted above, in some implementations it may be advantageous or desirable to form depletion electrodes 252 using a different conductive material than that used to form gate electrodes 226a and 226b.

Continuing with the implementation shown by structure 260 in FIG. 2F, flowchart 100 may conclude with formation of channel layer 262, shown as a P type channel layer, channel contacts 264, also P type, and N type source regions 266, adjacent gate trenches 234a and 234b (160). Channel layer 262 and channel contacts 264 may be formed through implantation and diffusion of a P type dopant, such as boron (B) into semiconductor substrate 212 so as to form channel layer 262 and channel contacts 264 over drift zone 216. Moreover, N type source regions 266 may be formed over drift zone 216 through implantation and diffusion of an N type dopant, such as phosphorus (P) or arsenic (AS), for example. In one exemplary implementation, diffusion of channel layer 262 and channel contacts 264 may be followed by a contact etch which removes N type species implanted in the region occupied by channel contact 252 prior to diffusion of the N type source implant. That contact etch may then be followed by diffusion of the N type source implant to form N type source regions 266.

Depletion electrodes 252 can be used to deplete drift zone 216 when the trench FET implemented using structure 260 is in the blocking state, when depletion electrodes 252 are tied to a low electrical potential, e.g., grounded or at a near ground potential. For example, in one implementation, depletion electrodes 252 may be electrically coupled to a source of the trench FET, such as by being coupled to N type source regions 266. In that exemplary implementation, depletion trenches 232 correspond to deep source trenches, while depletion electrodes 252 may be characterized as buried source electrodes. It is noted that electrical connection of depletion electrodes 252 and N type source regions 266 may be implemented using a metal contact layer overlying structure 260 (not shown in FIG. 2F), or may occur in the third dimension with respect to the cross-sectional view shown in FIG. 2F.

Use of depletion electrodes 252 to deplete drift zone 216 can confer several advantages. For example, in one implementation, depletion trenches 232 including depletion electrodes 252 enable structure 260 to sustain a higher breakdown voltage for higher voltage operation. Alternatively, depletion trenches 232 including depletion electrodes 252 enable an increased conductivity for drift zone 216 while sustaining a desired breakdown voltage. The latter implementation may be desirable because increased conductivity in drift zone 216 is associated with a reduced R_{dson}.

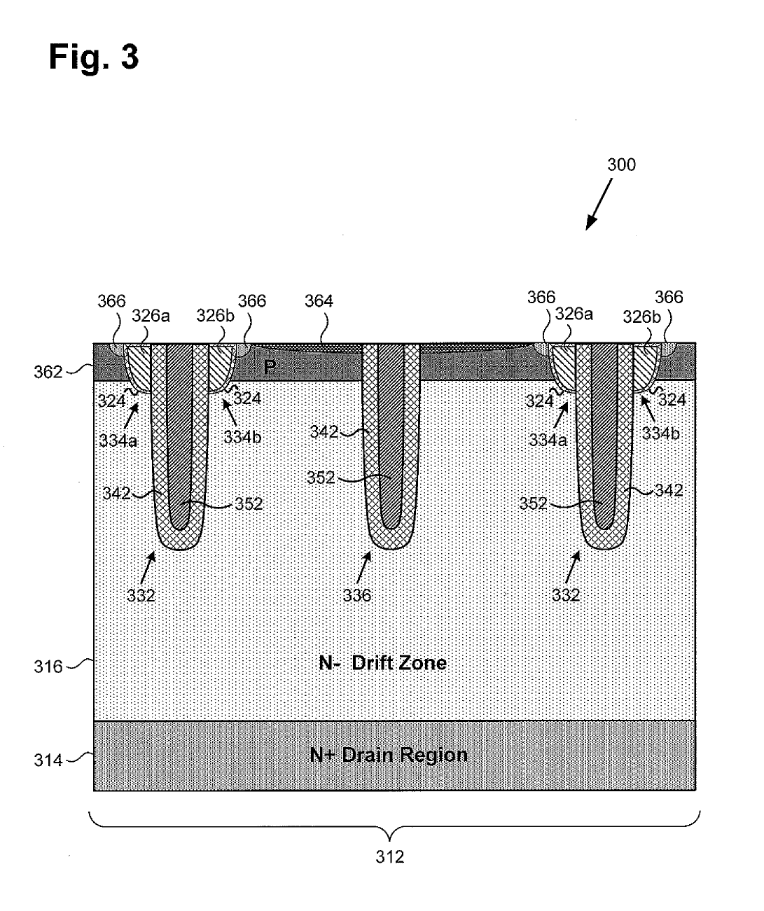

Turning now to FIG. 3, structure 300 shows a cross-sectional view of an exemplary reduced gate charge trench FET according to another implementation. Structure 300 includes semiconductor substrate 312 including drain region 314, drift zone 316, channel layer 362, and channel contact 364. As shown in FIG. 3, structure 300 also includes depletion trenches 332 and 336 extending through channel layer 362 into drift zone 316. Depletion trenches 332 and 336 each includes thick trench insulator 342 and depletion electrode 352 disposed therein. In addition, depletion trenches 332, but not depletion trench 336, have thin gate dielectric 324 and gate electrodes 326a and 326b adjoining thick trench insulator 342. Also shown in FIG. 3 are gate trenches 334a and 334b, and N type source regions 366.

Gate trenches 334a and 334b, and depletion trenches 332 including respective depletion electrodes 352 and thick trench insulator 342 correspond respectively to gate trenches 234a and 234b, and depletion trenches 232 including respective depletion electrodes 252 and thick trench insulator 242, in FIG. 2F. In addition, thin gate dielectric 324 and gate electrodes 326a and 326b adjoining thick trench insulator 342, in FIG. 3, correspond respectively to thin gate dielectric 224 and gate electrodes 226a and 226b adjoining thick trench insulator 242, in FIG. 2. Moreover, semiconductor substrate 312, drain region 314, drift zone 316, channel layer 362, channel contact 364, and N type source regions 366, in FIG. 3, correspond respectively to semiconductor substrate 212, drain region 214, drift zone 216, channel layer 262, channel contacts 264, and N type source regions 266, in FIG. 2F.

Structure 300, in FIG. 3, differs from structure 260, in FIG. 2F, in that depletion trench 336 is situated adjacent gate trenches 326a and 326b adjoining depletion trenches 332. In other words, depletion trench 336 is formed between depletion trenches 332 and is not adjoined by gate trenches 326a and 326b. As a result, the channel density of structure 300 is reduced relative to the channel density of structure 260, in FIG. 2F. For example, where a unit cell of structures 260 or 300 is defined as being bordered by successive depletion trenches, structure 300 can be seen to have approximately one half the channel density of structure 260. Consequently, implementation of structure 300 results in a still lower total gate charge Q_{g} compared to structure 260.

It is noted that, despite the reduction in channel density associated with structure 300, for certain higher voltage applications, for example approximately 80 V to approximately 100 V operation, or higher, the reduction in channel density of structure 300 may produce only a nominal increase in R_{dson}. Consequently, for some applications, a trench MOSFET implementing structure 300 may achieve a reduced gate charge Q_{g}, while concurrently achieving reduction in the product R_{dson}*Q_{g}.

Thus, by configuring a gate electrode and a gate dielectric so as to be adjoined by a thicker trench insulator used to line a depletion trench of a trench FET, the capacitance between the gate electrode and the silicon or other group IV layer in which a gate trench including the gate electrode is disposed can be reduced. As a result, the gate charge for the trench FET is reduced, enhancing performance for virtually all high frequency switching applications. In addition, for some applications, for example those requiring a FET operating voltage of approximately eighty volts (80 V) to approximately 100 V, or higher, the implementations disclosed in the present application can also advantageously result in a reduction in the product R_{dson}*Q_{g}.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described herein, but many rearrangements, modifications, and substitutions are possible without departing from the scope of the present disclosure.

1. A trench FET comprising:
a semiconductor substrate including a drain region and a drift zone over said drain region;
first and second gate trenches including a gate dielectric and respective gate electrodes disposed therein, over said drain region;
a depletion trench situated between said first and second gate trenches, said depletion trench including a trench insulator;
said trench insulator adjoining said gate electrodes and said gate dielectric so as to reduce a gate charge of said trench FET.

2. The trench FET of claim 1, wherein said trench insulator is substantially thicker than said gate dielectric.

3. The trench FET of claim 1, wherein said depletion trench has a depletion electrode disposed therein.

4. The trench FET of claim 1, wherein said depletion trench has a depletion electrode disposed therein, said depletion electrode electrically coupled to a source of said trench FET.

5. The trench FET of claim 1, wherein said depletion trench is at least one and a half times deeper than said first and second gate trenches.

6. The trench FET of claim 1, further comprising another depletion trench situated adjacent at least one of said first and second gate trenches.

7. The trench FET of claim 1, further comprising third and fourth gate trenches including a gate dielectric and respective gate electrodes, situated adjacent said first and second gate trenches, and another depletion trench situated between said third and fourth gate trenches.

8. The trench FET of claim 1, further comprising a channel layer including source regions formed over said drift zone.

9. The trench FET of claim 1, wherein said drift zone comprises an epitaxial silicon layer.

10. The trench FET of claim 1, wherein said trench FET is an n-channel FET.

11. A method for fabricating a trench FET, said method comprising:
providing a semiconductor substrate including a drain region, and a drift zone over said drain region;
forming a broad trench lined by a gate dielectric and having a conductive body disposed therein, over said drain region;
forming a depletion trench through said conductive body and said broad trench to produce first and second gate trenches including said gate dielectric and respective gate electrodes;
lining said depletion trench with a trench insulator;
said trench insulator adjoining said gate electrodes and said gate dielectric so as to reduce a gate charge of said trench FET.

12. The method of claim 11, wherein said trench insulator is substantially thicker than said gate dielectric.

13. The method of claim 11, further comprising forming a depletion electrode in said depletion trench.

14. The method of claim 11, further comprising forming a depletion electrode in said depletion trench, and electrically coupling said depletion electrode to a source of said trench FET.

15. The method of claim 11, wherein said depletion trench is at least one and a half times deeper than said first and second gate trenches.

16. The method of claim 11, further comprising forming another depletion trench adjacent at least one of said first and second gate trenches.

17. The method of claim 11, further comprising forming third and fourth gate trenches including a gate dielectric and respective gate electrodes, situated adjacent said first and second gate trenches, and another depletion trench situated between said third and fourth gate trenches.

18. The method of claim 11, further comprising forming a channel layer including source regions over said drift zone.

19. The method of claim 11, wherein said drift zone comprises an epitaxial silicon layer.

20. The method of claim 11, wherein said trench FET is an n-channel FET.
